(19) United States
(12) Patent Application Publication
(10) Pub. No.: US 2026/0237596 A1
(43) Pub. Date: Aug. 13, 2026

(54) DIRECT DIGITIZING DETECTION CHANNEL

(71) Applicant: ASML Netherlands B.V., Veldhoven (NL)

(72) Inventor: Yongxin WANG, San Ramon, CA (US)

(73) Assignee: ASML Netherlands B.V., Veldhoven (NL)

(21) Appl. No.: 19/150,757

(22) PCT Filed: Jan. 10, 2024
(86) PCT No.: PCT/EP2024/050516

§ 371 Date: Jul. 24, 2025

Related U.S. Application Data
(60) Provisional application No. 63/441,759, filed on Jan. 27, 2023.

(51) Int. Cl. H01J 37/26; H01J 37/28

(52) U.S. Cl. CPC H01J 37/265; H01J 37/28; H01J 2237/24495; H01J 2237/2487

(57) ABSTRACT

A charged particle detector includes plurality of sensing elements, each sensing element having a sensing element level circuit for processing detection signals. The sensing element circuit comprises a threshold circuit for preventing noise at the sensing element from passing to detection cells in the sensing element level circuit. The threshold circuit may be a thyristor, or other solid state current controlling device, which may tum on to conduct current when a threshold voltage or current is reached, and turn off when the current falls below a holding current. The detection cells may be direct digitizing cells capable of producing measurement values in discrete programmable units.

### CROSS-REFERENCE TO RELATED APPLICATIONS

This application claims priority of US application 63/441,759 which was filed on Jan. 27, 2023 and which is incorporated herein in its entirety by reference.

### TECHNICAL FIELD

The description herein relates to detectors, and more particularly, to detectors that may be applicable to charged particle detection.

### BACKGROUND

Detectors may be used for sensing physically observable phenomena. For example, some charged particle beam tools, such as electron microscopes, comprise detectors that receive charged particles projected from a sample and that output detection signals. Detection signals may be used to reconstruct images of sample structures under inspection and may be used, for example, to reveal defects in the sample. Detection of defects in a sample is increasingly important in the manufacturing of semiconductor devices, which may include large numbers of densely packed, miniaturized integrated circuit (IC) components. Inspection systems may be provided for this purpose. For example, a charged particle (e.g., electron) beam microscope, such as a scanning electron microscope (SEM) or a transmission electron microscope (TEM), capable of resolution down to less than a nanometer, serves as a practical tool for inspecting IC components having a feature size that is sub-100 nanometers. Electron microscopes work by irradiating a sample with an electron beam, then detecting secondary or backscattered electrons (or other types of secondary particles) on a detector. The secondary particles may form one or more beam spots on the detector surface.

Some detectors include a pixelated array of multiple sensing elements. A pixelated array can be useful because it may allow a detector configuration to be adapted to the size and shape of beam spots formed on the detector. When multiple primary beams are used, with multiple secondary beams incident on the detector, a pixelated array may be segregated into different regions of the detector associated with different beam spots. Each region may form its own group of sensing elements (pixels) that are used to detect individual beam spots.

Some detectors include charged particle counting functionality. With continuing miniaturization of semiconductor devices, inspection systems may use lower and lower beam currents in charged particle beam tools. Existing detection systems may be limited by signal-to-noise ratio (SNR) and system throughput, particularly when beam current reduces to, for example, pico-ampere ranges. Electron counting has been proposed to enhance SNR and to increase throughput in electron beam inspection systems, wherein the intensity of an incoming electron beam is acquired by counting the number of electrons that reach the detector, and then analyzing the frequency of electron arrival events.

### SUMMARY

Some embodiments of the present disclosure provide a sensing element level circuit of a charged particle detector. The sensing element level circuit may comprise: a threshold circuit configured to be put into an on state or an off state in response to an output of a sensing element of the charged particle detector; and a first digitizing cell. The on state may allow the threshold circuit to conduct current from the sensing element to the first digitizing cell of the sensing element level circuit. The off state may prevent the threshold circuit from conducting current from the sensing element to the first digitizing cell of the sensing element level circuit.

Some embodiments of the present disclosure provide a method of reducing noise in a charged particle detector. The method may comprise: enabling a threshold circuit of the charged particle detector to be put into an on state or an off state in response to an output of a sensing element of the charged particle detector; and, generating an image based on charge received at a sensing element level readout circuit of the charged particle detector. The on state may allow the threshold circuit to conduct current from the sensing element to a first digitizing cell of the sensing element level readout circuit. The off state may prevent the threshold circuit from conducting current from the sensing element to the first digitizing cell of the sensing element level readout circuit.

It is to be understood that both the foregoing general description and the following detailed description are exemplary and explanatory only and are not restrictive of the disclosed embodiments, as may be claimed.

### BRIEF DESCRIPTION OF DRAWINGS

FIG. 1 is a schematic diagram illustrating an exemplary charged-particle beam inspection system, consistent with embodiments of the present disclosure.

FIG. 2 is a schematic diagram illustrating an exemplary multi-beam beam tool, consistent with embodiments of the present disclosure that can be a part of the exemplary charged-particle beam inspection system of FIG. 1.

FIGS. 3A-C are diagrams illustrating signals at a sensing element output, according to a comparative embodiment.

FIG. 4 is a diagram illustrating a charged particle counting detector, according to a comparative embodiment.

FIG. 5 is a diagram illustrating a sensing element level circuit, consistent with embodiments of the present disclosure.

FIG. 6 is a diagram illustrating an array of sensing elements and sensing element level readout circuits, consistent with embodiments of the present disclosure.

FIG. 7 is a diagram illustrating an example digitizing cell, consistent with embodiments of the present disclosure.

FIG. 8 is a diagram illustrating an example digitizing cell, consistent with embodiments of the present disclosure.

FIG. 9 is a flowchart illustrating a method that may be useful for charged particle beam measurement, consistent with embodiments of the disclosure.

FIG. 10 is a flowchart illustrating a method that may be useful for charged particle beam measurement, consistent with embodiments of the disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing charged-particle beams (e.g., electron beams), the disclosure is not so limited. Other types of charged particle beams may be similarly applied. Furthermore, other imaging systems may be used, such as optical imaging, photodetection, x-ray detection, or the like.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (“SCPM”). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

The working principle of a SEM is similar to a camera. A camera takes a picture by receiving and recording intensity of light reflected or emitted from people or objects. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture,” the electron beam may scan through the wafer (e.g., in a line-by-line or zig-zag manner), and the detector may receive exiting electrons coming from a region under electron-beam projection (referred to as a “beam spot”). The detector may receive and record exiting electrons from each beam spot one at a time and join the information recorded for all the beam spots to generate the inspection image. Some SEMs use a single electron beam (referred to as a “single-beam SEM”) to take a single “picture” to generate the inspection image, while some SEMs use multiple electron beams (referred to as a “multi-beam SEM”) to take multiple “sub-pictures” of the wafer in parallel and stitch them together to generate the inspection image. By using multiple electron beams, the SEM may provide more electron beams onto the structures for obtaining these multiple “sub-pictures,” resulting in more electrons exiting from the structures. Accordingly, the detector may receive more exiting electrons simultaneously and generate inspection images of the structures of the wafer with higher efficiency and faster speed.

Electrons exiting an object, such as a wafer, and then received by the detector of the SEM may cause the detector to generate electrical signals (e.g., current signals or voltage signals) commensurate to the energy of the exiting electrons and the intensity of the electron beam. For example, the amplitudes of the electrical signals may be commensurate to the charge or energy of the received exiting electrons. The detector may output the electrical signals to an image processor, and the image processor may process the electrical signals to form the image of structures of the wafer. A multi-beam SEM system uses multiple electron beams for inspection, and a detector of the multi-beam SEM system may have multiple sections to receive them. Each section may have multiple sensing elements and may be used to form a “picture” of a sub-region of the wafer. The “picture” generated based on signals from each section of the detector may be merged to form a complete picture of the inspected wafer.

A further issue facing detectors, particularly with charged particle counting detectors, is a high SNR in low beam current systems. For example, charged particle counting detectors may have a complex signal readout architecture at the level of each individual sensing element. Each sensing element in a charged particle counting detector may be coupled to its own array of signal detection cells, each of which may be configured to register individual electron arrival events. Because they are configured to detect such fine signals, the signal detection cells may be negatively impacted even by low levels of noise in the detection channel.

Additionally, the designs required to achieve such fine detection prevent counting detectors from being usable in conventional applications with much higher beam currents. Conventional detectors have a similar problem, in that they may not be useable in very low beam current applications such as charged particle counting. Thus, both conventional and counting detectors may suffer from a low dynamic range that prevents them from being employed in a wide range of beam currents.

Embodiments of the present disclosure provide a charged particle detector with an improved sensing element level readout circuit design. Each sensing element level circuit in the detector may comprise an array of digitizing cells. The digitizing cells may be similar to signal detection cells in a charged particle counting detector. However, rather than counting individual charged particle arrival events, the digitizing cells may measure the overall energy flow introduced into a detection channel by multiple arrival events. The digitizing cells may directly produce digital values of the energy flow that may be read out by a control unit of the sensing element level circuit. The digitizing cells may achieve a high dynamic range that allows them to be used in both high and low beam current applications.

The sensing element level readout circuit may include a threshold circuit configured to prevent low level noise from reaching the digitizing cells. For example, the threshold circuit may comprise a solid state current controlling device (SSCCD) such as a silicon controlled rectifier (SCR). The SSCCD may be configured to turn on and conduct current when it receives a signal above a threshold. Once turned on, the SSCCD may turn off again to cease conducting current when the current drops below a holding current threshold of the SSCCD. In this way, low-level noise may be prevented from reaching the digitizing cells between individual arrival events.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing detection systems and detection methods in systems utilizing electron beams (“e-beams”). However, the disclosure is not so limited. Other types of charged particle beams may be similarly applied. Furthermore, systems and methods for detection may be used in other imaging systems, such as optical imaging, photon detection, x-ray detection, ion detection, or the like.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Relative dimensions of components in drawings may be exaggerated for clarity. Within the following description of drawings, the same or like reference numbers refer to the same or like components or entities, and only the differences with respect to the individual embodiments are described.

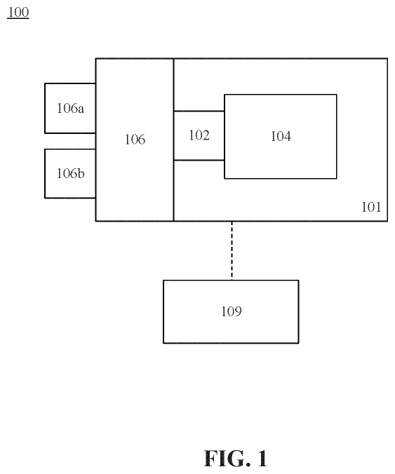

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

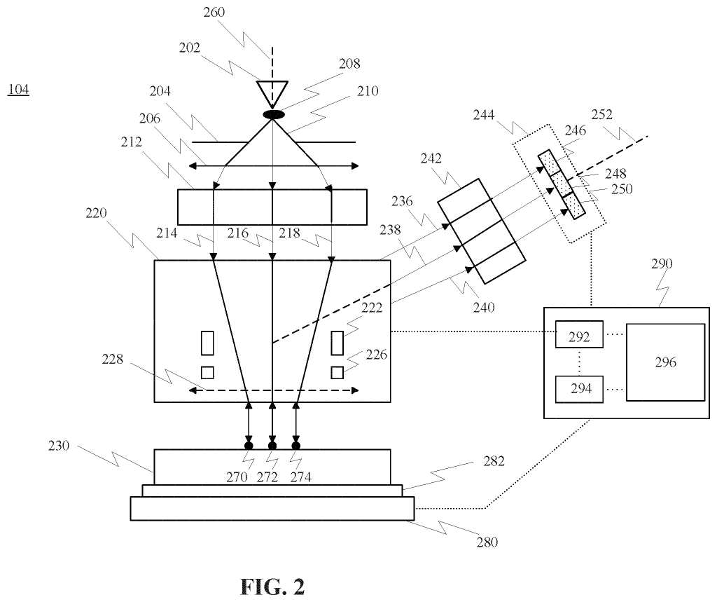

FIG. 2 illustrates a schematic diagram of an exemplary multi-beam beam tool 104 (also referred to herein as apparatus 104) and an image processing system 290 that may be configured for use in EBI system 100 (FIG. 1), consistent with embodiments of the present disclosure.

Beam tool 104 comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and charged-particle detection device 244 can be aligned with a secondary optical axis 252 of apparatus 104.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 2, embodiments of the present disclosure are not so limited. For example, in some embodiments, the apparatus 104 may be configured to generate a first number of beamlets. In some embodiments, the first number of beamlets may be in a range from 1 to 1000. In some embodiments, the first number of beamlets may be in a range from 200-500. In an exemplary embodiment, an apparatus 104 may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies ≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and SEs depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2). The quantity of BSEs and SEs may be more or fewer (or even the same) than the injected electrons of primary charged-particle beam 210.

The images generated by SEM may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SEM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

For ease of explanation without causing ambiguity, electrons are used as examples in some of the descriptions herein. However, it should be noted that any charged particle may be used in any embodiment of this disclosure, not limited to electrons. For instance, a source in a charged-particle beam tool can emit one or more charged particles, such as electrons, protons, ions, muons, or any other particle carrying electric charges. Furthermore, some embodiments of the present disclosure may use photons instead of charged particles, such as light in the visible, UV, DUV, EUV, x-ray, or any other wavelength range. For example, in a photon embodiment, a secondary beam spot may refer to reflected, refracted, diffracted or scattered light from a sample upon which a primary light beam is incident. Therefore, while detectors in the present disclosure may be disclosed with respect to electron detection, some embodiments of the present disclosure may be directed to detecting other charged particles or photons.

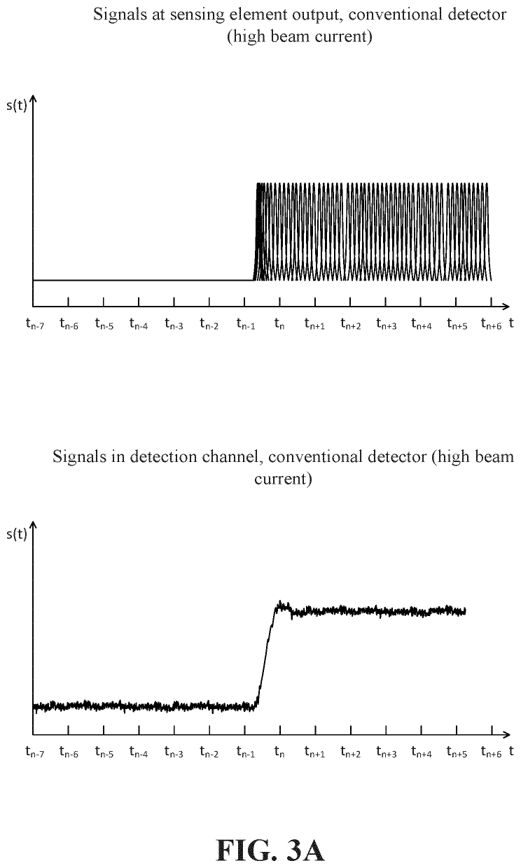

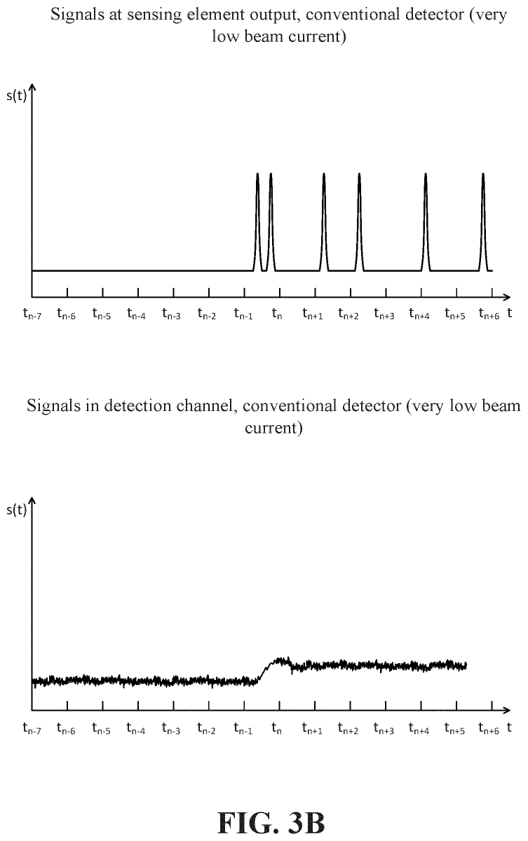

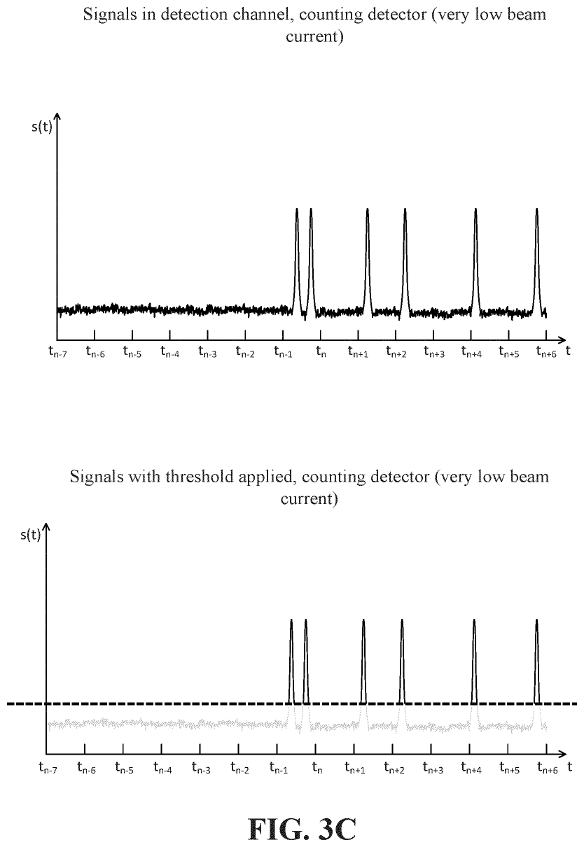

FIG. 3A and B illustrate a relationship between a signal value s(t) created by electron arrivals at a sensing element output and the corresponding values s(t) in a detection channel for two different beam current levels of a conventional charged particle detector. For example, with respect to the high beam current of FIG. 3A, signals at the sensing element output show a series of sharp peaks from individual arrival events. However, the corresponding signal in a detection channel is less distinct. The overlapping peaks may be smoothed out into an integrated or weighted average signal, and the detection channel adds a noise component due to, e.g., transistors, amplifiers, thermal noise in resistors, etc. In the situation of FIG. 3B, with a very low beam current such as, e.g., in the pA range, noise from the detection channel may become the dominant contributor to overall noise in a resulting image. At very low beam currents, the frequency of charged particle arrival events may be considerably lower than in high beam current applications. A smoothing of the few tall, sharp peaks in the sensing element output may result in broad and flattened signal in the detection channel. Meanwhile, the noise component may remain essentially unchanged from the situation of FIG. 3A, such that the few arrival events may be very difficult to distinguish from the noise. Because magnitudes of the signal and noise are so similar, increasing a gain in the detection channel will not help to differentiate one from the other.

FIG. 3C illustrates a signal value s(t) in a detection channel for the very low beam current of FIG. 3B when detected using a charged particle counting detector. In a counting-type detector, as illustrated in the top graph of FIG. 3C, individual peaks may be detected separately rather than as an averaged signal. This may result in a vastly improved SNR at each local event. Further, as shown in the lower graph, a threshold circuit may be configured to prevent the signal from passing unless it exceeds a predetermined threshold (indicated by dashed line in the figure). This prevents noise components from passing to readout circuitry at the sensing element level, resulting in a substantially noise-free detection of individual charged particle arrivals.

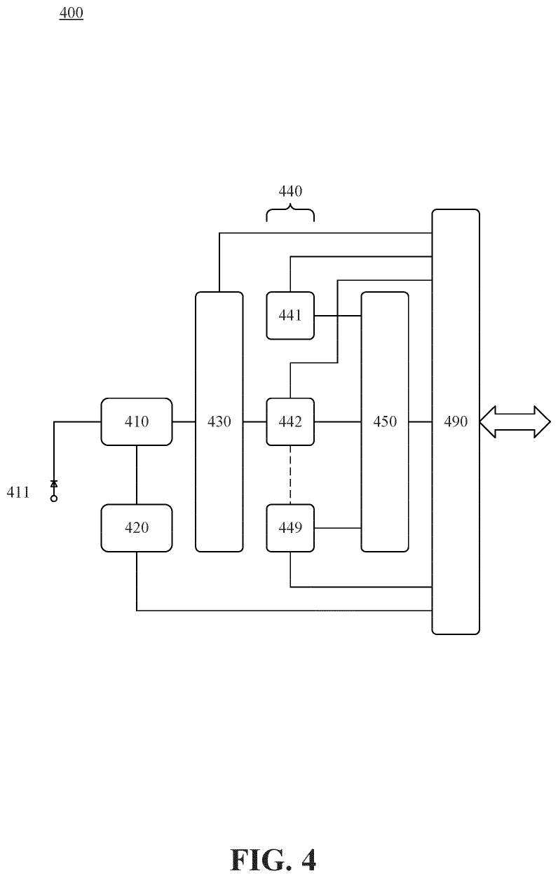

FIG. 4 illustrates a circuit 400 for charged particle counting in a comparative embodiment. Circuit 400 may be one of a plurality of circuits, each of which is provided for a corresponding sensing element in an array detector. Circuit 400 may be configured to process signals generated from sensing element 411. Sensing element 411 may be configured to generate a response to a charged particle event. A charged particle event may include an electron arrival event. For example, in response to the arrival of an incoming electron at sensing element 411, sensing element 411 may be configured to generate charges or current due to the energy of the incoming electron. The charges or current may be generated within the sensing element and may be fed to circuitry connected to the sensing element. In some cases, the circuitry may be integrated with the sensing element.

As shown in FIG. 4, circuit 400 includes an input stage 410, a threshold detector 420, a storage cell multiplexer 430, an array 440 of storage cells, a converter 450, and a control unit 490. Array 440 may include a plurality of storage cells including a first storage cell 441, a second storage cell 442, and so on, up to, for example, an Nth storage cell 449. Storage cells 441 through 449 may include charge storage cells.

Input stage 410 may be configured to extract substantially all charges from sensing element 411 quickly after they are generated. Threshold detector 420 may be configured to detect a signal level of incoming current from sensing element 411 and determine that a charged particle arrival event occurs. Threshold detector 420 may be configured to detect a start or a stop of a charged particle arrival event and trigger the recording of information from sensing element 411.

Circuit 400 may further include a storage cell multiplexer 430 configured to selectively connect the output of input stage 410 to a plurality of storage cells 441-449 of storage cell array 440. Each storage cell may be configured to integrate a signal from the output of input stage 410. Integration may refer to a process of obtaining an accumulated value of charge or current over time (e.g., area under a curve). Integration may begin when threshold detector 420 indicates that an arrival event has started and end when threshold detector 420 indicates that the arrival event is over. The outputs of individual storage cells may be connected to converter 450, such as an analog-to-digital converter (ADC), for example.

Circuit 400 may be configured to interrogate the storage cells of array 440 after integration in a storage cell is complete. Interrogation may refer to obtaining information from a storage cell, such as a voltage value for determining, e.g., an energy level of an electron arrival event. Integration and interrogation may be ongoing when a detector is in operation. Integration results stored in storage cells may be interrogated and counting results may be sent to control unit 490. Such operations may occur at the sensing element level. Thus, for all sensing elements of a detector, separate integration and interrogation processes may be performed. Data may be processed and sent to an upper level control unit of the detector. An upper level control unit may be configured to determine electron counts based on data from lower level control units (e.g., control unit 490 at the sensing element level of a detector).

Control unit 490 may be configured to perform various functions associated with circuit 400. For example, control unit 490 may be configured to: (i) control the operation of sensing element level circuitry, (ii) generate data based on the detection results of electron arrival events, (iii) communicate with a higher level control unit (not shown), and (iv) communicate with neighboring control units in neighboring sensing element level circuits that are similar or identical to, e.g., circuit 400.

Further discussion of electron counting circuitry may be found in International Application No. PCT/EP2021/068676, which is incorporated by reference in its entirety, and U.S. Provisional Application No. 63/408,755, which is incorporated by reference in its entirety.

Analog pipeline and storage cell array architecture of FIG. 4 may be complex and costly to manufacture. Increased complexity introduces an increased risk of malfunction. In addition to cost and risks of malfunction, the architecture may have an undesirably high power consumption within each sensing element level readout circuit. Further, circuit 400 may only be suitable for very low beam currents, and may not be capable of handling the high beam currents of conventional inspection operations.

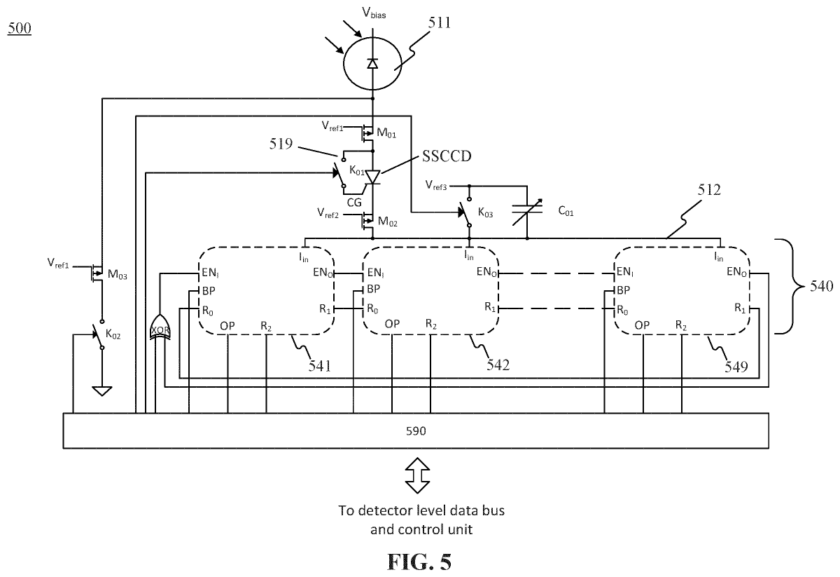

FIG. 5 illustrates a simplified block diagram of a readout design for a sensing element level circuit 500 with its corresponding sensing element 511, consistent with embodiments of the present disclosure. Sensing element 511 may be similar to, e.g., any of sensing elements 311-314 of FIGS. 3A-C. Sensing element 511 may be a charged particle sensing element configured to generate an electrical signal in response to a charged particle arrival event. The electrical signal may be, e.g., an electrical charge, current or voltage. In some embodiments, sensing element 511 may be a photon sensing element. In addition to various switches, transistors and other circuit components, sensing element level circuit 500 may comprise: threshold circuit 519, digitizing cell array 540, and sensing element level control unit 590.

Threshold circuit 519 may be configured to conduct current from sensing element 511 to digitizing cell array 540. Threshold circuit 519 may comprise, e.g., switch K₀₁ and solid state current controlling device SSCCD. When enabled by, e.g., closing switch K₀₁, solid state current controlling device SSCCD may be enabled to turn on and conduct current from sensing element 511 when a signal output from sensing element 511 exceeds a predetermined trigger threshold. The trigger threshold may be, e.g., a voltage, current or other signal value. Solid state current controlling device SSCCD may be configured to turn off again when the level of current being conducted falls below a predetermined holding current value. Both the trigger threshold and the holding current may be programmable. For example, the trigger threshold may be set to a value above a noise component in circuit 500, or it may be set to a value that indicates that a charged particle arrival event has occurred at sensing element 511. The holding current may be set to a value that indicates that substantially all charge generated at sensing element 511 by the charged particle arrival event has been passed on to digitizing cell array 540 by threshold circuit 519. In some embodiments, the holding current may be a value that corresponds to the trigger threshold. The holding current may be chosen to substantially avoid a situation in which it passes only a noise component in the detection signal.

Solid state current controlling device SSCCD may be, e.g., a silicon controlled rectifier, a thyristor or another solid state element configured to conduct current in one direction. For example, solid state current controlling device SSCCD may comprise four layers of alternating p-type and n-type material. Solid state current controlling device SSCCD may comprise, e.g., a combination of one pnp bipolar transistor and one npn bipolar transistor. Solid state current controlling device SSCCD may include control gate CG configured to turn the solid state controlling device on or off in response to a charged particle arrival event. For example, when charge is generated at the electrodes of a sensing element due to, e.g., a charged particle arrival event, the charge may generate a signal that produces a voltage value at control gate CG. If the voltage value at control gate CG meets or exceeds the trigger threshold, control gate CG may trigger the solid state current controlling device to be in an “on” state in which current may pass through it. Solid state current controlling device SSCCD may remain in this on state until most of the charge from the sensing element has been extracted out and passed on through threshold circuit 519. When the current falls below a holding current value, the solid state current controlling device SSCCD may be configured to switch from an on state to an off state, and further conduction may be prevented. Thus, solid state current controlling device SSCCD may be configured to self-deactivate after a current pulse drops below the holding current.

Solid state current controlling device SSCCD may be configured to extract charge from sensing element 511 rapidly and efficiently when a charged particle arrival occurs. For instance, solid state current controlling device SSCCD may be configured as a thyristor. When triggered to the on state, a thyristor may advantageously exhibit a negative resistance, such that current may be increased at low voltages. This may result in rapid extraction of charge from the sensing element 511 so that speed of the detection process may be improved.

The on/off function of a thyristor or other SSCCD may represent a great improvement over prior configurations, such as threshold detector 420 and related control circuitry of FIG. 4. The control gate of, e.g., a thyristor may advantageously require a short response time, e.g., on the order of nanoseconds, to trigger the thyristor to an on state and begin conducting current. In this way the charge extraction process may be initiated quickly after a charged particle arrival event occurs. Similarly, the thyristor may shut itself down automatically when a holding current threshold is met. The thyristor may therefore be configured to operate in a rapid manner with low power consumption and a simplified control architecture. In addition to thyristors or silicon controlled rectifiers, other solid state current controlling devices may be configured to achieve these advantages.

Circuit 500 may comprise transistors M₀₁, M₀₂, and M₀₃. The transistors may be, e.g., MOSFET or other transistors and may be configured as, e.g., common gate amplifiers. The common gate amplifier arrangement may be used to stabilize voltage values in circuit 500 and its associated sensing element 511. In some embodiments, transistors M₀₁, M₀₂, or M₀₃ may be omitted.

Transistor M₀₁ may be arranged between sensing element 511 and threshold circuit 519. Transistor M₀₁ may be, e.g., a MOSFET configured as a common gate amplifier with a reference voltage V_{ref1}. Transistor M₀₁ may stabilize the voltage at the anode of sensing element 511. As a result, bias voltage across the sensing element may be stabilized. The speed and parasitic capacitance variations that would have resulted from bias voltage fluctuations during normal operation may be minimized by the introduction of transistor M₀₁. Transistor M₀₁ may additionally minimize the presence of residue charges in the sensing element during operation. Finally, the common gate amplifier formed by transistor M₀₁ may further perform the function of a charge extractor. Unwanted electrical effects, such as parasitic capacitance, may cause fluctuations in a charge extraction flow during a charged particle detection process. Transistor M₀₁ may have low input impedance. This may help to better extract the charge from sensing element 511 and reduce the impact of parasitic capacitance in the sensing element on the detection results. Similar to transistor M₀₁, transistor M₀₂ may be, e.g., a MOSFET configured as a common gate amplifier with a reference voltage V_{ref2}. Transistor M₀₂ may stabilize fluctuations at a cathode side of solid state current controlling device SSCCD.

Transistor M₀₃ and switch K₀₂ may form a charge release path from sensing element 511. For example, switch K₀₂ may be, e.g., an analog switch configured to selectively pass or block the flow of charge based on a control signal from control unit 590. Circuit element M₀₃ may be optionally included, e.g., as a current or voltage buffer. Circuit element M₀₃ may be, e.g., a MOSFET configured as a common gate amplifier having a reference voltage V_{ref1}. When sensing element 511 is not in use, switch K₀₂ may be closed to drain any charges generated at sensing element 511 so that they do not accumulate.

Threshold circuit 519 may pass current to input bus 512. Input bus 512 may be coupled to storage capacitor C₀₁ and to each analog input Iin of digitizing cells 541-549 in digitizing cell array 540. Together, storage capacitor C₀₁ and digitizing cell array 540 may be configured to store and process charged particle detection events into digitally readable information. For instance, as described below, the digitizing cells of array 540 may be configured to successively receive and process charge associated with one or more charged particle arrival events. When a presently operating digitizing cell has reached a predetermined storage capacity, it may activate a next digitizing cell to continue storing and processing charge from the one or more charge particle arrival events.

During this process, storage capacitor C₀₁ may act as a storage buffer to provide continuous and uninterrupted processing of charged particle detection events. Any signal charges extracted out of sensing element 511 which are not immediately moved into a signal digitizing cell may first be stored in storage capacitor C₀₁. The charge may then pass from storage capacitor C₀₁ into a digitizing cell when storage capacitance in a digitizing cell becomes available. In this way, signal loss may be minimized, and detector accuracy may be improved.

Furthermore, storage capacitor C₀₁ may be monitored, and its capacitance may be adjusted, as needed. For example, a voltage comparator having a reference voltage generator (not shown in FIG. 5) with predefined value may be provided to detect whether a voltage across the terminals of storage capacitor C₀₁ exceeds an upper threshold during a normal detection operation. If the threshold is exceeded, an overflow flag or other alert may be generated to indicate that the sensing element level circuit 500 is not configured to process the full input signal it is receiving under the present settings. This may indicate that the detection results contain an error. For instance, an overflow flag may indicate that not all current from the output of sensor 511 was successfully processed by digitizing cell array 540. Overflow information may comprise, e.g., a first type, a second type, or other classes of overflow information as disclosed in U.S. Publication No. 2019/0379682, which is incorporated by reference in its entirety.

Storage capacitor C₀₁ may have an adjustable capacitance to correct for such errors. If overflow happens, sensing element level control unit 590 may send control signals to storage capacitor C₀₁ to increase its capacitance. Storage capacitor C₀₁ may also comprise an array of storage capacitors. The array of storage capacitors may be coupled to each other by, e.g., an interconnection switch matrix. In this configuration, capacitance adjustment may be achieved by selectively adding and removing capacitors from operation via the switch matrix. There may further be provided a second voltage comparator and second reference voltage generator with a second predefined value. The second voltage comparator and second reference generator may be used to detect a lower threshold level of the voltage across the terminals of storage capacitor C₀₁. If, within a predefined interval after sensing element level circuit 500 is enabled, the voltage across the capacitor C₀₁ stays below the lower threshold, it may indicate that the capacitance of storage capacitor C₀₁ may be reduced. A control signal may be sent control unit 590 to storage capacitor C₀₁ to reduce its capacitance. Capacitance may thus be increased or reduced to optimize performance of each individual each sensing element level circuit. Such adjustment may also be controlled at other levels of a control architecture, such as a detector level control unit.

Digitizing cell array 540 may comprise a plurality of digitizing cells, such as digitizing cells 541, 542, etc., up to 549. Digitizing cell 549 may be an Nth digitizing cell in the array. In other words, array 540 may generally comprise any number of digitizing cells, with digitizing cell 549 representing the final digitizing cell in array 540. Each digitizing cell may comprise a plurality of inputs and outputs. For example, each digitizing cell may comprise: analog signal input Iᵢₙ; enable signal input EN_{I}; enable signal output ENₒ; bypass input BP; operation status output OP; first reset signal input R₁; second reset signal input R₂; and reset signal output R₀.

Analog signal input Iᵢₙ of the digitizing cell may be configured to receive an electrical signal from sensing element 511 via threshold circuit 519 and input bus 512, and to pass the electrical signal to internal circuitry (not shown in FIG. 5) configured to store the electrical signal. For example, the internal circuitry may comprise a storage capacitor. Operation status output OP may be configured to output a detection result signal from the digitizing cell to control unit 590. Operation status output OP may comprise information about energy stored in the storage capacitor. For instance, a signal at operation status output OP may indicate that a digitizing cell has been charged to its predetermined capacity by the incoming detection signal. Alternatively, operation status output OP may be used by control unit 590 to read the residue energy level stored in the digitizing cell as further discussed below.

Enable signal input EN_{I} may be configured to receive an enabling signal. Enable signal input EN_{I} may pass the enabling signal to internal circuitry (not shown in FIG. 5) that enables the digitizing cell to begin receiving and processing charges. In an enabled state, for example, the internal circuitry of the digitizing cell may be configured to receive and store a signal from sensing element 511. Enable signal output EN_{O} may be configured to pass a further enabling signal to a further enable signal input EN_{I} in a next digitizing cell in the array. For example, enable signal output EN_{O} of digitizing cell 541 may pass an enabling signal to the enable signal input EN_{I} of next digitizing cell 542. A digitizing cell may receive an enabling signal via enable signal input EN_{I} when it is to be activated for signal detection, and it may send an enabling signal via enable signal output EN_{O} when it is time to activate a next digitizing cell. For example, digitizing cell 541 may send an enabling signal via enable signal output EN_{O} to digitizing cell 542 after, e.g., digitizing cell 541 has been charged to a predetermined level by a detection signal from sensing element 511. The enable signal input EN_{I} of each digitizing cell may be coupled to the enable signal output EN_{O} of the immediately preceding digitizing cell. This arrangement forms a ring structure of digitizing cells so that they may continuously activate each other in cycles for successive signal processing. Enable signal input EN_{I} of first digitizing cell 541 may be coupled to enable signal output EN_{O} of Nth digitizing cell 549 by intervening logic gate XOR to complete the ring structure.

A digitizing cell may be in an inactive state after sending the enabling signal via enable signal output EN_{O} to activate the next digitizing cell. In the inactive state, a digitizing cell may not be configured to receive further charge from sensing element 511. However, the digitizing cell may perform other functions, such as storing charge or generating output signals, in the inactive state.

A reset circuit may comprise first reset input R₁, second reset input R₂, and reset output R₀. The reset circuit may cause internal circuitry (not shown) to reset the digitizing cell to an initial state. For example, the initial state may be an inactive state in which the digitizing cell is ready to be enabled by an enabling signal at enable signal input EN_{I}. Resetting the digitizing cell to an initial state may comprise, e.g., discharging any charge stored within the digitizing cell, such as in a storage capacitor, and ceasing the transmission of an enabling signal at its enable signal output EN_{O}. A reset operation may take place when a digitizing cell receives a first reset signal at first reset input R₁ or a second reset signal at second reset input R₂. The first reset signal may be output from reset output R₀ of a further digitizing cell. For example, digitizing cell 541 may send a reset output signal “backward” to digitizing cell 549 at substantially the same time that it sends an enabling signal “forward” to digitizing cell 542. Digitizing cell 542 will not be reset until the digitizing cell it is enabling completes its own detection period and outputs its own first reset signal from its own reset output R₀. This arrangement ensures that the digitizing cell being presently used for signal detection continues to receive an enabling signal at its enabling signal input EN_{I} until the enabling signal is not needed.

Digitizing cell bypass input BP may be configured to receive a bypass signal and activate bypass circuitry (not shown in FIG. 5) of its digitizing cell. For example, when bypass circuitry is activated, the digitizing cell may be placed in a bypass state. In the bypass state, the digitizing cell may not be configured for signal detection. For example, the digitizing cell may not be configured to receive or store charge from sensing element 511 in the bypass state. The digitizing cell may be configured to pass any enabling signal forward to a next digitizing cell instead of using the enabling signal to activate its own circuitry. Likewise, a bypassed digitizing cell may be configured to pass a first reset signal backward to a previous digitizing cell instead of using the reset signal to reset its own circuitry.

A digitizing cell may be bypassed, e.g., if it is not functioning properly or if fewer digitizing cells are desired. For example, when the frequency of charged particle arrival events is low enough that not all digitizing cells are needed, it may be desirable to bypass unnecessary digitizing cells to isolate their circuitry, minimize parasitic parameters and reduce power consumption. Additionally, the bypass function may be used when a digitizing cell has detected and stored a signal from a charged particle arrival event, but the signal has not yet been processed by signal processing circuitry. In this case, the digitizing cell may remain inactive until its signal has been processed and the digitizing cell has been reset to an initial state in which it is ready to again be enabled by a further enabling signal.

Logic gate XOR may be configured, e.g., as an XOR or other logic gate device. Logic gate XOR may be configured to activate a first digitizing cell 541 in array 540 based on a left input from control unit 590 or a right input from enable signal output EN_{O} of final digitizing cell 549 in array 540. For example, logic gate XOR may be configured to receive a binary signal, represented by 0 or 1, at each of the left and right inputs seen in FIG. 5. Logic gate XOR may be configured to output a signal value of 1 only when its inputs are dissimilar. For example, when a left input and right input are both 1 or both 0, logic gate XOR may not output a signal value of 1. However, when a first input is 1 and the other input is 0, logic gate XOR may be configured to output a signal value of 1. Logic gate XOR may be used to initiate and repeat a cycle of signal detections in array 540 as further discussed below. Logic gate XOR may be part of control unit 590.

Control unit 590 may be configured for bidirectional data flow. Control unit 590 may be configured for various functions and may be similar to, e.g., control unit 109 of FIG. 1 or 290 of FIG. 2. Control unit 590 may be configured to control sensing element 511 and digitizing cells 541-549. Control unit 590 may be configured to receive and process inputs from the outputs of digitizing cells. For example, control unit 590 may be configured to receive operation status signals from operation status output OP. Control unit 590 may be configured to generate and send output signals to the inputs of digitizing cells. For example, control unit 590 may be configured to send digitizing cell bypass signals to bypass input BP and second reset signals to second reset input R₂. Control unit 590 may comprise further inputs and outputs not illustrated here. For example, further inputs and outputs may functionally couple control unit 590 to sensing element 511, detector-level data and control circuitry, and other sensing element level readout circuitry of neighboring sensing elements.

A detection operation of circuit 500 of FIG. 5 is now described using the above inputs, outputs and other components, consistent with embodiments of the present disclosure. The operation may take place in a detector, such as electron detection device 244 of electron beam tool 104 of FIG. 2. The detector may be part of, e.g., EBI system 100 of FIG. 1. Alternatively, the operation may take place in another electron detector or another type of detector, such as a proton, photon or other detector. Therefore, while embodiments may discuss operations and elements in terms of electrons, it should be understood that other embodiments are possible.

When sensing element 511 is to be enabled for signal detection, control unit 590 may place sensing element 511 in a sensing state. For example, control unit 590 may open switch K₀₂ to disconnect sensing element 511 from a charge release path. Control unit may further close switch K₀₁ to enable threshold circuit 519 to conduct current from sensing element 511. For example, the closing of switch K₀₁ may short control gate CG to the anode of solid state current controlling device SSCCD, changing the way it responds to signals it receives at its anode. This allows solid state current controlling device SSCCD to be triggered on when a signal (such as a voltage value) from its associated sensing element exceeds a predetermined trigger threshold. When solid state current controlling device SSCCD is triggered, it may act as a switch to rapidly conduct charge from the anode to the cathode. The SSCCD may remain stay in the on state until most of the charges from the sensing element are extracted out and passed to either storage capacitor C₀₁, signal digitizing cells 541-549, or both at the same time. When current passing through the SSCCD falls below the holding current, it may self-deactivate by turning from an on state to an off state.

Control unit 590 may further output a signal value of 1 as a start signal to the left input of logic gate XOR. Because digitizing cell 549 is in an initial state, it is not presently outputting a signal value of 1 to the right input of logic gate XOR via enable signal output EN_{O}. Thus, enable signal output EN_{O} of digitizing cell 549 causes an output of a signal value of 0 (wherein a signal value of 0 may refer to no signal or to a binary signal value other than 1). Because the left and right inputs of logic gate XOR are dissimilar, logic gate XOR may output a signal value of 1 as an enabling signal to enable signal input EN_{I} of digitizing cell 541. Later when digitizing cell 541 transmits an enabling signal from enable signal output EN_{O} to the enable signal input ENI of the next digitizing cell, such as digitizing cell 542, control unit 590 may cease outputting the signal value 1 to the left input of logic gate XOR, such that the left input is receiving a signal value of 0. For example, control unit 590 may determine that digitizing cell 541 has output the enabling signal based on an operating status output signal from operating status output OP of digitizing cell 541.

When enable signal input EN_{I} of digitizing cell 541 receives the enabling signal from logic gate XOR, the digitizing cell is enabled for receiving and storing charge from sensing element 511. For example, the enabling signal may close an internal switch within digitizing cell 541 to allow current to pass to an internal storage capacitor. All other digitizing cells in array 540 may remain in an inactive state, such as the initial state or a bypass state.

When a charged particle landing even occurs at sensing element 511, an analog signal may be generated and transmitted to analog signal input Iᵢₙ of the presently enabled digitizing cell, such as digitizing cell 541. Digitizing cell 541 may remain enabled, e.g., until it completes a charge measurement event. For example, a charge measurement event may be complete when a storage capacitor of the digitizing cell is charged to a predetermined level by the signal from sensing element 511. The completion of a charge measurement event may trigger the transmission of an enabling signal at enable signal output EN_{O} of digitizing cell 541 and a change in the operation status signal at its operation status output OP. For example, in some embodiments the operation status signal may change from 1 to 0.

The operation status signal may indicate to control unit 590 that, e.g., a charge measurement event has been completed in digitizing cell 541. Control unit 590 may use this signal to determine that a predetermined amount of charge has been stored in digitizing cell 541. The predetermined amount of charge may correspond to an amount of charge stored in the storage capacitor when its voltage reaches a predetermined reference voltage. Thus, the operating status output signals OP from each digitizing cell may represent digitized signals indicating a charged particle beam measurement in predetermined increments (such as, e.g., a predetermined unit measurement of charged particle beam intensity, a predetermined unit measurement of charged particle arrivals at sensing element 511, etc.). The predetermined increments may be the same for all digitizing cells in array 540, or may be different for some or all of the digitizing cells. The predetermined increments may be summed by, e.g., control unit 590, a detector level control unit or other signal processing circuitry. The summation may indicate a total charged particle beam measurement during a measurement period at sensing element 511. The summation may be expressed as, e.g., a total beam intensity, or it may indicate an estimated or actual charged particle count at sensing element 511.

Along with the generation of the operation status signal, the completion of a charge measurement event may trigger further signals in digitizing cell 541. For example, a signal may be generated at enable signal output EN_{O} of digitizing cell 541 to activate the next digitizing cell 542 by transmitting the enabling signal to enable signal input EN_{I} of digitizing cell 542. Alternatively, if digitizing cell 542 is in a bypass state, the enabling signal may pass directly through digitizing cell 542 and onto a next digitizing cell until the enabling signal reaches a digitizing cell that is not in a bypass state. Additionally, a signal may be generated to disable digitizing cell 541 from receiving further charge. For example, the signal may open an internal switch within digitizing cell 541 to prevent further current from passing to the internal storage capacitor. Finally, a reset signal may be generated at reset output R₀. The reset signal may be passed to a first reset input R₁ of a previous digitizing cell, such as Nth digitizing cell 549. Alternatively, if Nth digitizing cell 549 is in a bypass state, the reset signal may pass directly through Nth digitizing cell 549 and onto, e.g., a first reset input R₁ of a further digitizing cell until the reset signal reaches a digitizing cell that is not in a bypass state. In this way, when a charge measurement event is completed at a first digitizing cell, the first digitizing cell may be automatically disabled, a next digitizing cell may be automatically enabled, and a previous digitizing cell may be automatically reset to an initial state.

A disabled digitizing cell may further be reset to the initial state directly from a controller. For example, control unit 590 may output a reset signal to second reset input R₂. A direct reset may be used when, e.g., a measurement process has ended, and one or more digitizing cells have not yet been reset.

The process may cycle through digitizing cells in array 540 until it reaches final digitizing cell 549. When final digitizing cell 549 outputs an enabling signal from its enable signal output EN_{O}, it may be transmitted as a signal value 1 to the right input of logic gate XOR. Because control unit has ceased delivery of the value 1 signal as discussed above, the left input receives a signal value of 0 and the logic gate XOR outputs a new enabling signal to enable signal input EN_{I} of first digitizing cell 541. In this way, array 540 of digitizing cells 541-549 may be cycled through repeatedly during a detection process as control unit 590 repeatedly collects measurements from operating status outputs OP.

In some embodiments, the process of acquiring measurement results may be further simplified. For instance, instead of processing operating status outputs OP at every digitizing cell, control unit 590 may measure a charged particle beam process by counting whole cycles of digitizing cell array 540. For example, an operating status output OP from, e.g., Nth digitizing cell 549 may indicate that a charge measurement event has been completed at every non-bypassed cell in the array. Alternatively, control unit 590 may be configured to receive a separate cycle output signal from, e.g., logic gate XOR or enable signal output EN_{O} of Nth digitizing cell 549. Logic gate XOR or enable signal output EN_{O} of Nth digitizing cell 549 may comprise a further output (not shown) coupled to control unit 590 for this purpose. In this way, the control unit may count a number of cycles of array 540 without receiving any operating status signals from operating status outputs OP until a residue count (below) is needed. When a number of cycles of array 540 is known, a full charged particle beam measurement for sensing element 511 may be achieved. For example, a control unit (such as control unit 590) may multiply the number of whole array cycles by the number of non-bypassed digitizing cells in array 540, and add in a residue (e.g., the number of leftover detections remaining in a final partial cycle of array 540). To obtain the residue, the operation states of all non-bypassed cells may be acquired by control unit 590. Using this cycle counting system, only the final residue cycle requires counting the measurement from every digitizing cell.

Furthermore, the cycle length may be modified as desired by bypassing a specific number of digitizing cells. This may be done to tailor the cycle length to operational conditions such as the beam current. For example, when beam current is high, the frequency of charged particle arrival events at a sensing element may be high, which may result in a high frequency of whole detection cycles. To reduce the cycle frequency, more signal detection cells may be brought into operation to increase the cycle length. However, when the frequency of charged particle arrival events is low (due to, e.g., low beam current), there may not be a need for so many signal detection cells. In this case, the cycle length may be shortened by bypassing some signal detection cells to reduce power consumption. In addition to a cycle length, the capacitance of each digitizing cell may be adjusted. For example, increasing the capacitance of a storage capacitor, or the voltage reference value at which storage is halted within a digitizing cell, may reduce the frequency of whole detection cycles for a given value of beam current.

The sensing element level readout circuit design 500 may provide a simple and cost-effective architecture configured to passively trigger the successive activation of a series of digitizing cells without requiring complex control circuitry to manage the process. The architecture of circuit 500 may achieve a high processing speed with low cost, low power consumption and low risk of failure. Further, circuit 500 may have a high enough dynamic range. For example, circuit 500 may be used in the very low beam current ranges in which electron counting detectors are used, and may also be applied to the high beam current applications of conventional detectors.

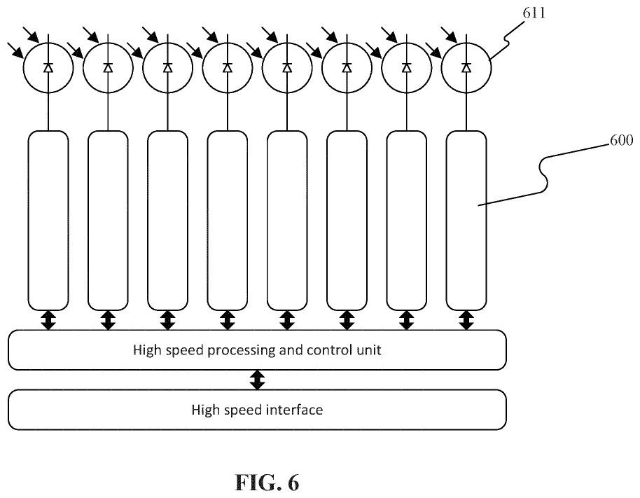

FIG. 6 illustrates a further advantage of the sensing element level readout circuit design consistent with embodiments of the present disclosure. FIG. 6 depicts a simplified example diagram of an array of sensing elements 611, each coupled to a sensing element level readout circuit 600. Sensing elements 611 may be similar to, for example, sensing element 511 of FIG. 5. Sensing elements 611 may be similar to, for example, any of sensing elements 311-314 of FIGS. 3A-C. Each sensing element level readout circuit 600 may be similar to, for example, sensing element level readout circuit 500 of FIG. 5.

Sensing element level readout circuits 600 may each be coupled directly to a high speed processing and control unit, such as a detector level processing and control unit or other signal processing and control circuitry. The high speed processing and control unit may in turn be coupled to a high speed interface which may be operatively coupled to a system control unit, such as controller 109 of FIG. 1 or image processing system 290 of FIG. 2. Unlike comparative systems such as electron counting detectors or conventional detectors, there may be no switch matrix or other interconnection, in analog or digital form, between adjacent sensing elements. Each sensing element may operate independently and the data from each sensing element may be individually accessible to a detector level processing and control unit. This may be made feasible by the greatly simplified signal processing and control architecture discussed above.

In addition to the advantages discussed above, it may be allowable to make the size of each sensing element 511 or 611 larger than those in, e.g., a pixelated electron counting detector. This is because the sensing element size is no longer constrained by the need to isolate individual charged particle arrival events to prevent temporal overlaps between two or more events in a single processing channel. Instead, charge may be measured in predefined increments according to the digitizing cells within each sensing element level circuit 600. Thus, for a given active area size on a charged particle detector, embodiments of the present disclosure allow a reduction in the overall number of sensing elements and corresponding sensing element level circuits. This, and the other advantages discussed above, may reduce the design complexity of charged particle readout circuits, leading to lower development risks, shorter development periods and lower development costs.

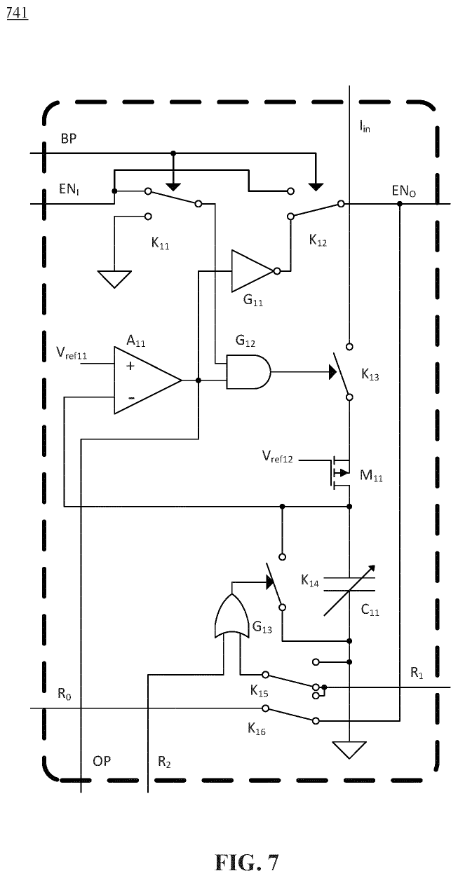

FIG. 7 illustrates a simplified diagram of an example of internal circuitry of a digitizing cell 741, consistent with some embodiments of the present disclosure. Digitizing cell 741 may be, for example, one possible implementation of digitizing cells 541-549 of FIG. 5. The various circuit elements and other components of digitizing cell 741 will be discussed in turn.

Digitizing cell 741 may further comprise an enable circuit and a bypass circuit configured to convert digitizing cell 741 from an initial state into, e.g., an enabled or bypass state based on enabling or bypass signals. In the initial state, for example, switch K₁₁ may be set to the higher position seen in FIG. 7, and switch K₁₂ may be set to the lower position. Switches K₁₃ and K₁₄ may each be set to an open state. In addition, digitizing cell 741 may have previously received a reset signal so that switch K₁₄ was closed to drain charge from storage capacitor C₁₁ prior to placing switch K₁₄ in the open state. Finally, reset switches K₁₅ and K₁₆ may each be set to the lower position seen in FIG. 7.

In the enabled state, digitizing cell 741 may be activated for detection. In the enabled state, digitizing cell 741 can be ready to pass charge from its associated sensing element (such as sensing element 511 in FIG. 5) to storage capacitor C₁₁. The enable circuit may comprise: enable signal input EN_{I}; enable signal output EN_{O}; and switches K₁₁ and K₁₂. The bypass circuit may comprise bypass signal input BP and switches K₁₁ and K₁₂. In some embodiments, the bypass circuit may be omitted.

The enable circuit may be configured to place digitizing cell 741 into the enabled state from the initial state. In the initial state configuration of switch K₁₁, an enabling signal may be transmitted from enable signal input EN_{I} to an upper input of AND gate G₁₂. The enabling signal may be, e.g., a high level voltage, or a value of “1” in digital terms. For example, if digitizing cell 741 is the first digitizing cell in an array (such as array 540 of FIG. 5), the enabling signal may be a signal value 1 from a logic gate (such as logic gate XOR or FIG. 5). Alternatively, the enabling signal may come from an enable signal output EN_{O} of a prior digitizing cell (such as Nth digitizing cell 549 of FIG. 5) in the array of digitizing cells. In the initial state, voltage comparator A₁₁ may be configured to output a further signal value 1 to the lower input of AND gate G₁₂, such that AND gate G₁₂ receives a signal value of 1 from both its upper and lower inputs. AND gate G₁₂ may then output a signal to close a further switch K₁₃, activating a charge detection circuit to place the digitizing cell 741 into the enabled state. For example, the closing of switch K₁₃ may allow current to pass from analog input Iᵢₙ to transistor M₁₁ and storage capacitor C₁₁.

Alternatively, the bypass circuit of digitizing cell 741 may receive a bypass signal at bypass signal input BP. For example, the bypass signal may be generated from a control unit (such as control unit 590 in FIG. 5). The bypass signal may cause switches K₁₁ and K₁₂ to reverse their positions from what is shown in FIG. 7, such that switch K₁₁ is in the lower position and switch K₁₂ is in the higher position. In this case, an enabling signal will not pass to AND gate G₁₂ from enable signal input EN_{I} . Instead, the enabling signal will pass through switch K₁₂ to enable signal output EN_{O} and exit the digitizing cell 741. Further, the upper input of AND gate G₁₂ may be connected to a signal ground or logic 0 by the new position of switch K₁₁ such that the upper input receives, e.g., a signal value of 0. Thus, switch K₁₃ may be prevented from closing and the charge detection circuit may not be enabled. The bypass signal may further cause switches K₁₅ and K₁₆ to toggle from their lower positions in FIG. 7 to the upper positions. In this state, switch K₁₅ may then couple right input of OR gate G₁₃ to signal ground or logic 0. Switch K₁₆ may pass any incoming reset signal back to a prior digitizing cell via reset output R₀.

Digitizing cell 741 may further comprise a charge detection circuit configured to receive current and store charge up to a predetermined amount. The charge detection circuit may comprise: analog switch K₁₃; transistor M₁₁ (such as a common gate amplifier as discussed above); storage capacitor C₁₁; voltage comparator A₁₁; NOT gate G₁₁; and AND gate G₁₂.

When digitizing cell 741 is enabled by closing switch K₁₃, and a charged particle arrival event at a sensing element (such as sensing element 511 of FIG. 5) triggers a threshold circuit (such as 519 in FIG. 5) to turn on, charge may be passed via analog input Iᵢₙ to storage capacitor C₁₁ and stored. A signal at storage capacitor C₁₁ may be output to voltage comparator A₁₁. In some embodiments, storage capacitor C₁₁ may form a part of the amplifier or buffer A₁₁. In some embodiments, storage capacitor C₁₁ may be a separate component. If the signal at storage capacitor C₁₁ reaches a predetermined level, voltage comparator A₁₁ may be configured to output a low level voltage (or 0 as digital data).

The 0 value signal may then be input to AND gate G₁₂, operating status output OP, and NOT gate G₁₁. When the signal value 0 is output to the lower input of AND gate G₁₁, it may cause switch K₁₃ to be actuated from close to open. This may disable digitizing cell 741 from passing further current to storage capacitor C₁₁. At the same time, the signal value 0 may be passed to operation status output OP as an operation status signal to a control unit such as, e.g., control unit 590 of FIG. 5. This may indicate to the control unit that digitizing cell 741 has completed a charge measurement event. For example, the operation status signal may indicate that digitizing cell 741 has detected an amount of charge according to a predetermined increment set by, e.g., a capacitance value of storage capacitor C¹¹. The control unit may assign a time stamp to the indicated charge measurement event based on the signal from operation status output OP. Finally, the signal value 0 may be converted at NOT gate G¹¹ to a value of 1. The value 1 signal may be passed via switch K₁₂ to enable signal output EN_{O} and reset output R₀. The signal at enable signal output EN_{O} may be passed to a next enable signal input EN_{I} of a next digitizing cell in the array to activate the next digitizing cell to continue detecting current. The signal at reset output R₀may be passed to a previous first reset input R₁ of a previous digitizing cell in the array to reset the previous digitizing cell.

Alternatively, the next digitizing cell in the array may be bypassed, in which case the enabling signal may pass through the next digitizing cell by the bypass circuit. This process may repeat until the enabling signal reaches a digitizing cell that is in an initial state and ready to be enabled. Similarly, the previous digitizing cell in the array may be bypassed, in which case the reset signal may pass through the previous digitizing cell by the bypass circuit.

In this way, digitizing cells may be automatically selected and enabled in rapid succession during a detection process. The sensing element-level architecture according to embodiments of the present disclosure may perform digitizing cell selection and switching with a fast, simplified, robust design. In addition, digitizing cells that are not needed may be disabled to reduce power consumption in the system. For example, in a bypassed digitizing cell, components that are not related to the enable circuit, bypass circuit, or transistor M₁₁, may be powered off.

Digitizing cell 741 may further comprise a reset circuit configured to reset the digitizing cell to an initial state. The reset circuit may comprise: first reset input R₁; second reset input R₂; OR gate G₁₃, switch K₁₄; and reset output R₀. A signal detection circuit may be reset to the initial state, e.g., after its enable signal no longer needs to be input to a next digitizing cell, or when a disabled or bypassed digitizing cell is brought back into operation. Alternatively, a reset signal may be sent simply to ensure that a digitizing cell is ready to be enabled. In some embodiments, a reset signal may be sent by a control unit when the digitizing cell is downstream from the presently enabled digitizing cell by a predetermined number of digitizing cells. For example, when a downstream digitizing cell is, e.g., five non-bypassed digitizing cells away from the presently enabled digitizing cell, the control unit may send a reset signal to ensure that the signal detection is ready to be enabled. In some embodiments, a reset signal may be sent automatically by another digitizing cell.

When a reset signal is input to either first reset input R₁ or second reset input R₂, OR gate G₁₃ may output a signal to close switch K₁₄. This may provide a path to clear the charge from storage capacitor C₁₁. When charge is cleared from storage capacitor C₁₁, a voltage at the lower input of voltage comparator A₁₁ may drop below reference voltage Vref₁₁. The resulting value 1 output at voltage comparator may then cause NOT gate G₁₁ to terminate the 1 signal at enable signal output EN_{O}. This may cease transmission of an enabling signal to an enable signal input EN_{I} of the next digitizing cell. At the same time, the 1 output to AND gate G₁₂ may prepare digitizing cell 741 to become enabled again when it receives an enabling signal at its own enable signal input EN_{I}. After reset is completed, digitizing cell 741 is again in the initial state and ready to receive an enabling signal at enable signal input EN_{I}.

The above circuits and components are provided by way of example, to illustrate one possible implementation of digitizing cells within a signal detection circuit, such as circuit 500 of FIG. 5. In some embodiments, the same or similar functions may be achieved by other combinations of switches, logic components, amplifiers and other circuit elements. For example, in some embodiments AND gate G₁₂ may comprise another logic gate, such as OR, XOR, NOT, NAND, NOR, XNOR, etc. In such embodiments, other circuitry may be configured to provide the appropriate inputs to logic gate G₁₂ so that it operates on switch K₁₃, or a component corresponding to switch K₁₃, in the desired manner. In general, a number of different configurations may be employed to perform the functions of, e.g., the enabling, bypass, charge detection, readout, and reset circuits in some embodiments of the present disclosure.

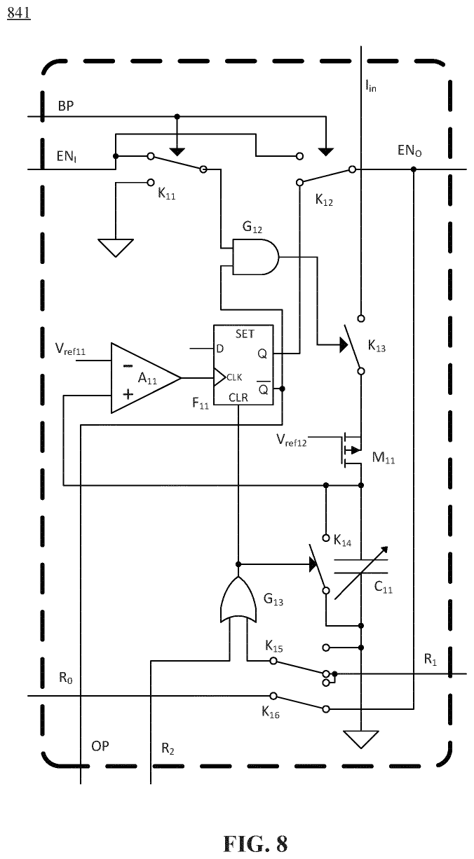

FIG. 8 illustrates a diagram of an example of internal circuitry of a digitizing cell 841, consistent with some embodiments of the present disclosure. Digitizing cell 841 may be, for example, one possible implementation of digitizing cells 541-549 of FIG. 5. Digitizing cell 841 may be similar to digitizing cell 741 except as discussed below.

Digitizing cell 841 may include a flip-flop circuit F₁₁ at an output of voltage comparator A₁₁. Flip-flop F₁₁ may be, e.g., a D-type flip-flop circuit. In some embodiments, flip-flop F₁₁ may be another type of flip-flop, latch or other logic circuit. In the initial state, flip-flop F₁₁, may be configured to output a signal value 1 from inverse output Q̅ to the lower input of AND gate G₁₂, while voltage comparator A₁₁ may be configured to output a 0 signal to clock input CLK of flip-flop F₁₁. Data input D may be configured to receive a constant signal value 1. Thus in the initial state, AND gate G₁₂ may be prepared to close switch K₁₃ and activate a charge detection circuit upon receiving a further signal value 1 to its upper input in the form of an enabling signal from enable signal input EN_{O}. Operating status output OP may also receive a signal value 1 from inverse output Q̅. At the same time, enable signal output EN_{O} may receive a 0 signal from output Q.

When a charge measurement event occurs in digitizing cell 841 such that a signal from storage capacitor C₁₁ exceeds reference voltage Vref₁₁, voltage comparator An may output a signal value 1 to the clock input CLK of Flip-flop F₁₁. The rising signal edge that occurs at clock input CLK during the change from signal 0 to signal 1 can trigger Flip-flop F₁₁ to pass the constant signal value 1 from data input D to its output Q, and change the inverse output Q̅ to signal value 0. Thus, the signal value 0 from inverse output Q̅ may cause AND gate G₁₂ to open switch K₁₃, preventing further charge from being passed to storage capacitor C₁₁. The signal value 0 may additionally be passed to operating status output OP to indicate the completion of a charge measurement event at digitizing cell 841. The signal value 1 from output Q may be passed as an enabling signal to enable signal output EN_{O} to activate a next non-bypassed digitizing cell.

First reset input R₁ of digitizing cell 841 may be coupled to an input of OR gate G₁₃. The output of OR gate G₁₃ may be coupled, not only to switch K₁₄ as was shown in FIG. 7, but also to a clear input CLR of flip flop F₁₁. When OR gate outputs a signal value 1 to clear input CLR based on a reset signal from first reset input R₁, flip flop F₁₁ may be configured to revert to the initial state. Similarly, a reset signal to second reset input R₂ from, e.g., a control unit (such as control unit 590 of FIG. 5) may accomplish the same function.

Adding a flip-flop F₁₁ to the digitizing cell 841 may result in a design that is more robust to, e.g., voltage fluctuations at storage capacitor C₁₁. For example, because clock input CLK is configured to react only to rising edges instead of a signal values 1 or 0, a change in output from 1 to 0 at voltage comparator An may not alter the output values at Q and Q̅. Therefore, after the voltage at storage capacitor C₁₁ has reached the predefined reference voltage Vref₁₁ subsequent fluctuations will not reverse the outputs to cause errors in operation of digitizing cell 841.

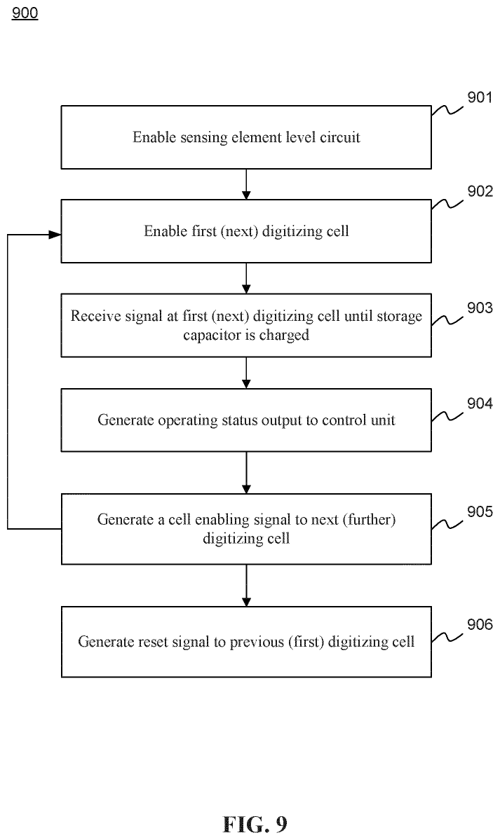

FIG. 9 is a flowchart illustrating a method 900 for charged particle detection, consistent with embodiments of the disclosure. Method 900 may be performed by, e.g., a sensing element level circuit in a detector of a charged-particle beam system (such as sensing element level circuits 500 or 600 of FIG. 5 or 6). The sensing element level circuit may include circuitry (e.g., a memory and a processor) programmed to implement method 900. A digitizing cell, such as digitizing cell 741 or 841 of FIG. 7 or 8, may be operated in accordance with method 900. Processing consistent with method 900 may be performed on a sensing element by sensing element basis. In the illustrated steps of method 900, the ordered terms (previous, first, next, further) outside parentheses indicate a first loop of method 900, while the ordered terms inside parentheses indicate a second loop of method 900.

At step 901, a sensing element circuit may be enabled to receive charge from a sensing element. For example, enabling the sensing element circuit may comprise enabling a threshold circuit to conduct current from the sensing element when it reaches a predetermined threshold. The threshold circuit may comprise a SSCCD. The SSCCD may be, e.g., a silicon controlled rectifier or other thyristor. For example, a circuit enabling signal may cause a switch to be closed that shorts a control gate of the SSCCD to an anode of the SSCCD.

At step 902, a first digitizing cell may be activated from an initial state, such as by a cell enabling signal. The first digitizing cell may be a first non-bypassed digitizing cell in an array of digitizing cells, such as array 540 of FIG. 5. The first digitizing cell may receive the cell enabling signal from, e.g., a logic gate based on an initiating signal from a control unit. For example, the enabling signal may cause a switch to be closed that allows current to flow to a storage capacitor of the first digitizing cell. Alternatively, the first digitizing cell of method 900 may receive a cell enabling signal from the enable signal output of a previous digitizing cell.

At step 903, the first digitizing cell may receive a detection signal from a sensing element. For example, when a detection signal from the sensing element reaches a predetermined trigger threshold, the SSCCD of the threshold circuit may be configured to turn on and begin conducting current to the digitizing cell. In some embodiments, method 900 may continue until the current being passed by the SSCCD of the threshold circuit falls below a holding current value, causing the threshold circuit to turn off and cease conducting current.

The sensing element may be coupled to an analog signal input of the first digitizing cell via, e.g., an input bus. The input bus may be coupled to every digitizing cell in the array as well as, e.g., a storage buffer. Current from the sensing element may be passed through the threshold circuit and input bus to a storage capacitor of the first digitizing cell. The storage capacitor may continue to receive charge until a signal at the storage capacitor reaches a predefined value. When the signal at the storage capacitor reaches the predefined value, a voltage comparator (such as A₁₁ of FIG. 7 or 8) or other circuit component may cause the switch of step 902 to be reopened so that no more current may flow to the storage capacitor of the first digitizing cell. In some embodiments, output of the voltage comparator may be coupled to, e.g., a flip flop circuit. The voltage comparator may additionally generate a plurality of signals discussed at steps 904-906 below.

At step 904, the output of the voltage comparator may comprise an operating status output signal. The operating status output signal may indicate to the control unit that a charge measurement event has occurred. For example, the control unit may generate a time stamp used for counting charge measurement events based on the operating status output signal. The operating status output signal may represent a digitized signal indicating a charged particle beam measurement in predetermined increments (such as, e.g., a predetermined unit measurement of charged particle beam intensity, a predetermined unit measurement of charged particle arrivals at sensing element 511, etc.). The predetermined increments may correspond to an amount of charge stored in the storage capacitor when its voltage reaches a reference voltage (such as Vref₁₁ in FIGS. 7 and 8).

At step 905, the output of the voltage comparator may comprise a cell enabling signal to activate a next digitizing cell in the array. The cell enabling signal may be generated substantially concurrently with the generation of the operating status output signal. The cell enabling signal may proceed from an enable signal output of the first digitizing cell to an enable signal input of the next digitizing cell. At this point, the process may return to step 902 and repeat for the next digitizing cell, as indicated in parentheses.

If, on the other hand, the next digitizing cell is in a bypass state, the cell enabling signal may be passed directly through the next digitizing cell along a bypass circuit to its own enabling signal output. The cell enabling signal may then be passed to a further enabling signal input of a further digitizing cell. This may continue until the cell enabling signal reaches a non-bypassed digitizing cell, at which point the non-bypassed digitizing cell may be enabled.

At step 906, the output of the voltage comparator may comprise a reset signal to reset a previous digitizing cell in the array. For example, the previous digitizing cell may be one that had been supplying a cell enabling signal to the first digitizing cell. After the charge measurement event was completed at step 903, the cell enabling signal from the previous digitizing cell was no longer need. The reset signal may be input to a first reset input of the previous digitizing cell to cause the previous digitizing cell to be reset to an initial state. Alternatively, the previous digitizing cell may be reset by inputting a reset signal from a control unit to a second reset input of the previous digitizing cell.

A second loop of method 900 is illustrated by the language in parentheses as discussed above. At a second iteration of step 902, the next digitizing cell may receive a cell enabling signal sent by the first digitizing cell in the first iteration of step 905. After the next digitizing cell receives and processes a charge measurement event at a second iteration of step 903, the next digitizing cell may generate a further enabling signal at a second iteration of step 905 to activate a further digitizing cell in the array.

Timestamps or other data corresponding to the operating status output signals may be summed to determine a measurement value of the sensing element. For example, the summation may indicate a total charged particle beam measurement during a measurement period at sensing element 511. The summation may be expressed as, e.g., a total beam intensity, or it may indicate an estimated or actual charged particle count at sensing element 511 for the measurement period.

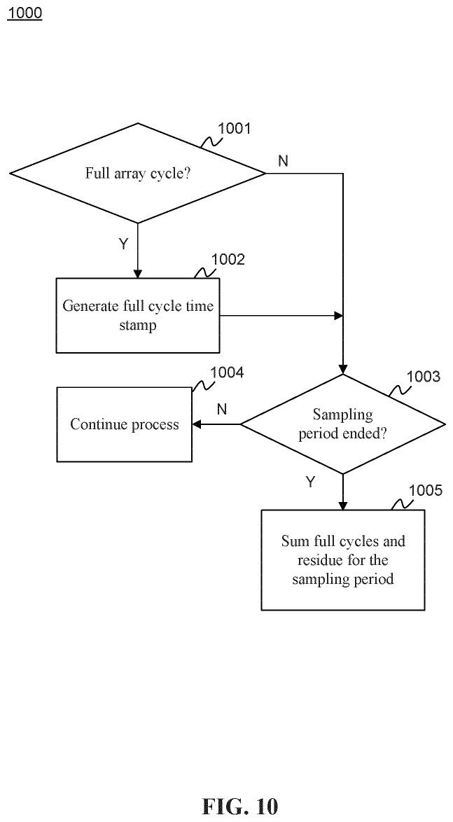

As an alternative to summing individual charge measurement events, method 1000 of FIG. 10 illustrates a cycle counting method, consistent with embodiments of the present disclosure. Method 1000 may be used, e.g., in conjunction with method 900. Method 1000 may count detection cycles during a sampling period set by, e.g., a control unit (such as control unit 590 of FIG. 5, a detector level control unit or another control unit).

At step 1001, the control unit may determine whether an operating status output (such as received at step 904 of FIG. 9) represents a full detection cycle of a digitizing cell array. For example, the control unit may determine whether the digitizing cell that generated the operating status output is a counting cell. A counting cell may be, e.g., a digitizing cell that is used to determine whether a full cycle of signal detection has occurred in an array of digitizing cells. For example, a first non-bypassed digitizing cell in the array, a last non-bypassed digitizing cell in the array, or both, may be utilized as a counting cell. In general, any digitizing cell may be utilized as a counting cell. Alternatively, method 1000 may comprise receiving a separate cycle output signal from, e.g., a logic gate XOR or final enable signal output EN_{O} of a final digitizing cell in the array. Further, a whole or partial cycle may be determined by other detection cells in the array. For example, if there is any digitizing cell other than the first or the last digitizing cell used as a counting cell, having a low value such as, e.g., 0 at its operating status output OP, the cycle may be determined not to be a whole cycle. In this way, the control unit may count a number of cycles of an array without summing every operating status signal from operating status outputs OP unless a residue count is needed.

If the detection does represent a full cycle, then the method 1000 may proceed to step 1002 where one full detection cycle timestamp is generated at the control unit. If the detection does not represent a full cycle, the method may proceed to step 1003.

At step 1003, the control unit may determine whether a sampling period has ended. A sampling period may take place based on predetermined timing settings set by, e.g., the control unit. In some embodiments the sampling period may correspond to a normal operation period of a charged particle beam apparatus. In some embodiments, the sampling period may correspond to another timing interval. If the sampling period has not ended, then the process continues as illustrated at step 1004. If sampling period has ended, then the method may proceed to step 1005.

At step 1005, a residue may be counted and summed with the full detection cycles. The residue may comprise time stamps from operating status signals retained by the control unit from the last partial cycle of digitizing cells. For example, if a digitizing cell array comprises ten active cells, then each full cycle represents ten charge measurement events. However, as discussed above, the sampling period may end part-way through a full detection cycle, e.g., when only five digitizing cells have registered a charge measurement event. In this case, the control unit may count individual operating status output signals from the digitizing cells to yield an accurate count of charge measurement events. The full cycles may be summed with the residue to determine a full count of charge measurement events. In the ten-cell example above, for instance, the control unit may multiply the number of full cycle counts by the number of active cells within the array (ten) and then add the residue (five in the example above). The summation of full cycles with the residue may represent a total count of charge measurement events during the sampling period. The method 1000 may be utilized to produce an accurate count of charge measurement events while minimizing the actual counting performed by signal processing circuitry.

Data from all the sensing element level circuits within a charged particle detector may be summed in a sampling period-by-sampling period manner. In this way, a detection result similar or identical to the counting methods above may be generated.

Further, the method 1000 may be customized for a detection operation by choosing an optimal number of digitizing cells in the array. Unneeded digitizing cells may be powered down and bypassed using signal bypass circuitry. Further, the value of each charge measurement event may be customized by altering an amount of charge stored within each digitizing cell during a single charge measurement event. This may be accomplished by, for example, adjusting a capacitance value of a storage capacitor or a voltage reference value of a voltage comparator.

Alternatively to counting method 1000, a higher level control unit, such as a detector-level control unit, may acquire the full cycle timestamps of each sensing element level circuit, e.g., as they are generated. The detector may thus sum all of the full cycle counts from every sensing element in the detector. From this summation of cycle counts, a detection signal may be generated to produce a charged particle beam image.

A non-transitory computer-readable medium may be provided that stores instructions for a processor of a controller (e.g., controller 109 in FIG. 1, image processing system 290 of FIG. 2 or controller 904 in FIG. 9) for detecting a charged-particle beam according to the exemplary flowcharts of FIGS. 13, 20, and 21 above, consistent with embodiments in the present disclosure. For example, the instructions stored in the non-transitory computer-readable medium may be executed by the circuitry of the controller for performing method 1300, 900 or 1000 in part or in entirety. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

Embodiments of the present disclosure may further be described by the following clauses:
1. A method of reducing noise in a charged particle detector, comprising:
   enabling a threshold circuit of the charged particle detector to be put into an on state or an off state in response to an output of a sensing element of the charged particle detector; and
   generating an image based on charge received at a sensing element level readout circuit of the charged particle detector, wherein
   the on state allows the threshold circuit to conduct current from the sensing element to a first digitizing cell of the sensing element level readout circuit; and
   the off state prevents the threshold circuit from conducting current from the sensing element to the first digitizing cell of the sensing element level readout circuit.
2. The method of clause 1, wherein the threshold circuit comprises a solid state current controlling device (SSCCD).
3. The method of clause 2, wherein the solid state current controlling device comprises a thyristor.
4. The method of clause 2, wherein enabling the threshold circuit comprises closing an enabling switch to couple a control gate of the SSCCD to an anode of the SSCCD in response to receiving a circuit enabling signal at the threshold circuit.
5. The method of clause 1, further comprising placing the threshold circuit in the on state in response to a voltage or current from the sensing element exceeding a predetermined trigger voltage or current of the threshold circuit.
6. The method of clause 5, wherein a value of the predetermined trigger voltage is determined based on preventing noise from being passed to the first digitizing cell.
7. The method of clause 1, further comprising placing the threshold circuit in the off state in response to a current from the sensing element falling below a predetermined holding current of the threshold circuit.
8. The method of clause 1, further comprising:
   storing charge from the sensing element in a buffer storage of the sensing element level readout circuit; and
   passing the charge from the buffer storage to the digitizing cell of the sensing element level readout circuit.
9. The method of clause 8, further comprising:
   in response to the buffer storage exceeding a buffer storage threshold, generating an overflow signal.
10. The method of clause 9, further comprising:
   adjusting a capacitance of the buffer storage element in response to the overflow signal.
11. The method of clause 1, further comprising:
   storing charge from the sensing element in a storage element of the first digitizing cell, and
   in response to the stored charge reaching a predetermined amount, generating an operating status output signal at an operating status output of the first digitizing cell, the operating status signal indicating the completion of a charge measuring event at the first digitizing cell.
12. The method of clause 11, further comprising:
   in response to the stored charge at the first digitizing cell reaching the predetermined amount, generating a first cell enabling signal from the first digitizing cell to a next digitizing cell of the sensing element level circuit to enable the next digitizing cell to store charge from the sensing element.
13. The method of clause 11, further comprising:
   in response to the stored charge at the first digitizing cell reaching the predetermined amount, opening a switch in the first digitizing cell to prevent further charge from being passed to the storage element of the first digitizing cell.
14. The method of clause 11, further comprising:
   in response to the stored charge at the first digitizing cell reaching the predetermined amount, generating a reset signal from the first digitizing cell to a previous digitizing cell.
15. The method of clause 14, further comprising:
   terminating a previous enabling signal from the previous digitizing cell in response to receiving the reset signal from the first digitizing cell.
16. The method of clause 11, further comprising:
   generating a time stamp at a control unit based on the operating status output signal; and
   selecting an image pixel sampling period,
   wherein generating the image based on charge received at the sensing element level readout circuit of the charged particle detector comprises:
   assigning a detection event to the image pixel sampling period based on the time stamp; and
   counting a total number of detection events assigned to the image pixel sampling period.
17. The method of clause 11, further comprising:
   determining, based on the operating status signal, that a plurality of digitizing cells of the sensing element level circuit have completed a charge measuring event.
18. The method of clause 1, wherein the sensing element comprises a PIN diode.
19. A sensing element level circuit of a charged particle detector, comprising:
   a threshold circuit configured to be put into an on state or an off state in response to an output of a sensing element of the charged particle detector; and
   a first digitizing cell; wherein
   the on state allows the threshold circuit to conduct current from the sensing element to the first digitizing cell of the sensing element level circuit; and
   the off state prevents the threshold circuit from conducting current from the sensing element to the first digitizing cell of the sensing element level circuit.
20. The sensing element level circuit of clause 19, wherein the threshold circuit comprises a solid state current controlling device (SSCCD).
21. The sensing element level circuit of clause 20, wherein the solid state current controlling device comprises a thyristor.
22. The sensing element level circuit of clause 20, wherein the threshold circuit is configured to be put into the on state or the off state by closing an enabling switch to couple a control gate of the SSCCD to an anode of the SSCCD in response to receiving a circuit enabling signal at the threshold circuit.
23. The sensing element level circuit of clause 19, wherein the threshold circuit is configured to be put into the on state in response to a voltage or current from the sensing element exceeding a predetermined trigger voltage or current of the threshold circuit.
24. The sensing element level circuit of clause 23, wherein a value of the predetermined trigger voltage is determined based on preventing noise from being passed to the first digitizing cell.
25. The sensing element level circuit of clause 19, wherein the threshold circuit is configured to be put into the off state in response to a current from the sensing element falling below a predetermined holding current of the threshold circuit.
26. The sensing element level circuit of clause 19, further comprising:
   a buffer storage configured to store charge from the sensing element in the sensing element level circuit and pass the charge to the digitizing cell of the sensing element level circuit.
27. The sensing element level circuit of clause 26, wherein the sensing element level circuit is further configured to:
   generate an overflow signal in response to the buffer storage exceeding a buffer storage threshold.
28. The sensing element level circuit of clause 27, wherein the sensing element level circuit is further configured to:
   adjust a capacitance of the buffer storage element in response to the overflow signal.
29. The sensing element level circuit of clause 19, further comprising:
   a storage element of the first digitizing cell configured to store charge from the sensing element;
   wherein the first digitizing cell is configured to generate an operating status output signal at an operating status output of the first digitizing cell in response to the stored charge reaching a predetermined amount, the operating status signal indicating the completion of a charge measuring event at the first digitizing cell.
30. The sensing element level circuit of clause 29, wherein the first digitizing cell is configured to:
   generate a first cell enabling signal from the first digitizing cell to a next digitizing cell of the sensing element level circuit in response to the stored charge at the first digitizing cell reaching the predetermined amount, to enable the next digitizing cell to store charge from the sensing element.
31. The sensing element level circuit of clause 29, wherein the first digitizing cell is configured to:
   open a switch in the first digitizing cell in response to the stored charge at the first digitizing cell reaching the predetermined amount, to prevent further charge from being passed to the storage element of the first digitizing cell.
32. The sensing element level circuit of clause 29, wherein the first digitizing cell is configured to:
   generate a reset signal from the first digitizing cell to a previous digitizing cell in response to the stored charge at the first digitizing cell reaching the predetermined amount.
33. The sensing element level circuit of clause 32, wherein the previous digitizing cell is configured to: terminate a previous enabling signal from the previous digitizing cell in response to receiving the reset signal from the first digitizing cell.
34. The sensing element level circuit of clause 29, wherein the sensing element level circuit is further configured to:
   generate a time stamp at a control unit based on the operating status output signal; and
   select an image pixel sampling period, and
   generate an image based on charge received at the sensing element level circuit of the charged particle detector by assigning a detection event to the image pixel sampling period based on the time stamp and counting a total number of detection events assigned to the image pixel sampling period.
35. The sensing element level circuit of clause 29, wherein the sensing element level circuit is further configured to:
   determine, based on the operating status signal, that a plurality of digitizing cells of the sensing element level circuit have completed a charge measuring event.
36. The sensing element level circuit of clause 19, wherein the sensing element comprises a PIN diode.
37. A digitizing cell of a charged particle detector, comprising:
   an analog signal input configured to receive a charge from a sensing element;
   an enable signal input configured to receive a first cell enable signal to activate the digitizing cell to store charge passed from the analog signal input;
   an operating status output configured to output an operating status signal representing a charge detection event of the stored charge; and
   an enable signal output configured to output a second enable signal to a further digitizing cell of the charged particle detector; and
   a reset signal input configured to receive a reset signal to reset the digitizing cell to an initial state.
38. The digitizing cell of clause 37, wherein the digitizing cell is configured to:
   generate the operating status output signal at the operating status output in response to the stored charge reaching a predetermined amount.
39. The digitizing cell of clause 37, wherein the digitizing cell is further configured to:
   generate the second enable signal in response to the stored charge reaching a predetermined amount, to enable the further digitizing cell to store charge from the sensing element.
40. The digitizing cell of clause 37, wherein the digitizing cell is further configured to:
   open a switch in the digitizing cell in response to the stored charge reaching a predetermined amount, to prevent further charge from being passed to a storage element of the digitizing cell.
41. The digitizing cell of clause 37, further comprising:
   a reset signal output configured to output a second reset signal to a reset signal input of a prior digitizing cell;
   wherein the digitizing cell is further configured to generate the second reset signal in response to the stored charge reaching a predetermined amount.
42. The digitizing cell of clause 41, wherein the digitizing cell is configured to terminate the second enable signal in response to receiving the reset signal at the reset signal input.
43. A non-transitory computer-readable medium storing a set of instructions that are executable by at least one processor of a charged particle beam apparatus to cause the apparatus to perform a method comprising:
   causing a charged particle detector to enable a threshold circuit of the charged particle detector to be put into an on state or an off state in response to an output of a sensing element of the charged particle detector; and
   generating an image based on charge received at a sensing element level readout circuit of the charged particle detector, wherein
the on state allows the threshold circuit to conduct current from the sensing element to a first digitizing cell of the sensing element level readout circuit; and
the off state prevents the threshold circuit from conducting current from the sensing element to the first digitizing cell of the sensing element level readout circuit.

It will be appreciated that the embodiments of the present disclosure are not limited to the exact construction that has been described above and illustrated in the accompanying drawings and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A sensing element level circuit of a charged particle detector, comprising:
a threshold circuit configured to be put into an on state or an off state in response to an output of a sensing element of the charged particle detector; and
a first digitizing cell; wherein
the on state allows the threshold circuit to conduct current from the sensing element to the first digitizing cell of the sensing element level circuit; and
the off state prevents the threshold circuit from conducting current from the sensing element to the first digitizing cell of the sensing element level circuit.

2. The sensing element level circuit of claim 1, wherein the threshold circuit comprises a solid state current controlling device (SSCCD).

3. The sensing element level circuit of claim 1, wherein the threshold circuit is configured to be put into the on state in response to a voltage or current from the sensing element exceeding a predetermined trigger voltage or current of the threshold circuit.

4. The sensing element level circuit of claim 3, wherein a value of the predetermined trigger voltage is determined based on preventing noise from being passed to the first digitizing cell.

5. The sensing element level circuit of claim 1, wherein the threshold circuit is configured to be put into the off state in response to a current from the sensing element falling below a predetermined holding current of the threshold circuit.

6. The sensing element level circuit of claim 1, further comprising:
a buffer storage configured to store charge from the sensing element in the sensing element level circuit and pass the charge to the digitizing cell of the sensing element level circuit.

7. The sensing element level circuit of claim 6, wherein the sensing element level circuit is further configured to:
generate an overflow signal in response to the buffer storage exceeding a buffer storage threshold.

8. The sensing element level circuit of claim 1, further comprising:
a storage element of the first digitizing cell configured to store charge from the sensing element;
wherein the first digitizing cell is configured to generate an operating status output signal at an operating status output of the first digitizing cell in response to the stored charge reaching a predetermined amount, the operating status signal indicating a completion of a charge measuring event at the first digitizing cell.

9. The sensing element level circuit of claim 8, wherein the first digitizing cell is configured to:
generate a first cell enabling signal from the first digitizing cell to a next digitizing cell of the sensing element level circuit in response to the stored charge at the first digitizing cell reaching the predetermined amount, to enable the next digitizing cell to store charge from the sensing element.

10. The sensing element level circuit of claim 8, wherein the first digitizing cell is configured to:
open a switch in the first digitizing cell in response to the stored charge at the first digitizing cell reaching the predetermined amount, to prevent further charge from being passed to the storage element of the first digitizing cell.

11. The sensing element level circuit of claim 8, wherein the first digitizing cell is configured to:
generate a reset signal from the first digitizing cell to a previous digitizing cell in response to the stored charge at the first digitizing cell reaching the predetermined amount.

12. The sensing element level circuit of claim 11, wherein the previous digitizing cell is configured to:
terminate a previous enabling signal from the previous digitizing cell in response to receiving the reset signal from the first digitizing cell.

13. The sensing element level circuit of claim 8, wherein the sensing element level circuit is further configured to:
generate a time stamp at a control unit based on the operating status output signal; and
select an image pixel sampling period, and
generate an image based on charge received at the sensing element level circuit of the charged particle detector by assigning a detection event to the image pixel sampling period based on the time stamp and counting a total number of detection events assigned to the image pixel sampling period.

14. The sensing element level circuit of claim 8, wherein the sensing element level circuit is further configured to:
determine, based on the operating status signal, that a plurality of digitizing cells of the sensing element level circuit have completed a charge measuring event.

15. A digitizing cell of a charged particle detector, comprising:
an analog signal input configured to receive a charge from a sensing element;
an enable signal input configured to receive a first cell enable signal to activate the digitizing cell to store charge passed from the analog signal input;
an operating status output configured to output an operating status signal representing a charge detection event of the stored charge;
an enable signal output configured to output a second enable signal to a further digitizing cell of the charged particle detector; and
a reset signal input configured to receive a reset signal to reset the digitizing cell to an initial state.

16. The digitizing cell of claim 15, wherein the digitizing cell is configured to:
generate the operating status output signal at the operating status output in response to the stored charge reaching a predetermined amount.

17. The digitizing cell of claim 15, wherein the digitizing cell is further configured to:
generate the second enable signal in response to the stored charge reaching a predetermined amount, to enable the further digitizing cell to store charge from the sensing element.

18. The digitizing cell of claim 15, wherein the digitizing cell is further configured to:
open a switch in the digitizing cell in response to the stored charge reaching a predetermined amount, to prevent further charge from being passed to a storage element of the digitizing cell.

19. The digitizing cell of claim 15, further comprising:
a reset signal output configured to output a second reset signal to a reset signal input of a prior digitizing cell; and
wherein the digitizing cell is further configured to:
generate the second reset signal in response to the stored charge reaching a predetermined amount, and
terminate the second enable signal in response to receiving the reset signal at the reset signal input.

20. A non-transitory computer-readable medium storing a set of instructions that are executable by at least one processor of a charged particle beam apparatus to cause the apparatus to perform operations comprising:
causing a charged particle detector to enable a threshold circuit of the charged particle detector to be put into an on state or an off state in response to an output of a sensing element of the charged particle detector; and
generating an image based on charge received at a sensing element level readout circuit of the charged particle detector, wherein:
the on state allows the threshold circuit to conduct current from the sensing element to a first digitizing cell of the sensing element level readout circuit; and
the off state prevents the threshold circuit from conducting current from the sensing element to the first digitizing cell of the sensing element level readout circuit.
